(19) United States
(12) Patent Application Publication
(10) Pub. No.: US 2013/0105939 A1
(43) Pub. Date: May 2, 2013

(54) SEMICONDUCTOR DEVICE

(71) Applicant: Panasonic Corporation, Osaka (JP)

(72) Inventor: Shinichi DOMAE, Osaka (JP)

(73) Assignee: PANASONIC CORPORATION, Osaka (JP)

(21) Appl. No.: 13/717,122

(22) Filed: Dec. 17, 2012

Related U.S. Application Data
(63) Continuation of application No. PCT/JP2011/003816, filed on Jul. 4, 2011.

(30) Foreign Application Priority Data
Dec. 21, 2010 (JP) 2010-284274

(51) Int. Cl. H01L 23/538

(52) U.S. Cl. CPC H01L 23/5384
USPC 257/528; 257/774

(57) ABSTRACT

A semiconductor device includes a first interposer, a semiconductor chip located above the first interposer, and a second interposer located in a region above the first interposer without the semiconductor chip. The first interposer includes a through electrode electrically coupled to the semiconductor chip, and a through electrode electrically coupled to the second interposer. A resin fills a space between the semiconductor chip and the second interposer.

### CROSS-REFERENCE TO RELATED APPLICATION

This is a continuation of International Application No. PCT/JP2011/003816 filed on Jul. 4, 2011, which claims priority to Japanese Patent Application No. 2010-284274 filed on Dec. 21, 2010. The entire disclosures of these applications are incorporated by reference herein.

### BACKGROUND

The present disclosure relates to semiconductor devices, and more particularly to semiconductor devices formed by stacking a plurality of semiconductor chips using interposers.

Conventionally, in formation of a three-dimensional stack of a plurality of semiconductor chips, through electrodes such as through silicon vias (TSVs) have been usually formed in the semiconductor chips before stacking. Through electrodes penetrate a semiconductor chip in a thickness direction to electrically couple electrodes on the front and back of the chip in a vertical direction.

However, in order to form through electrodes, it is necessary to add complicated processing to a process of manufacturing a semiconductor chip, and the entire process becomes complicated.

In order to address the problem, a technique of forming a three-dimensional stack of semiconductor chips without through electrodes is suggested (see, for example, Japanese Patent Publication No. 2007-123753).

The three-dimensional stack of the semiconductor chips without through electrodes shown in Japanese Patent Publication No. 2007-123753 will be described hereinafter with reference to FIGS. 5-7.

FIGS. 5 and 6 are a cross-sectional view and a top view illustrating a semiconductor chip unit, which forms the three-dimensional stack including the semiconductor chips according to the conventional art. In a semiconductor chip unit 4 shown in FIGS. 5 and 6, a semiconductor chip 1 without through electrodes is mounted above an interposer 3. A base material 31 of the interposer 3 is provided with a plurality of through electrodes 32. An interconnect layer 33 electrically coupled to the through electrodes 32 is formed on a first principal surface of the interposer 3, above which the semiconductor chip 1 is mounted. A plurality of columnar post electrodes 34 electrically coupled to the interconnect layer 33 are provided around the edge of the interconnect layer 33 to surround the semiconductor chip 1. Terminal electrodes 14 are formed on the surface of the semiconductor chip 1. The terminal electrodes 14 are flip-chip bonded to electrode pads (not shown) on the surface of the interconnect layer 33. Terminal electrodes 35 electrically coupled to the through electrodes 32 are formed on a second principal surface of the interposer 3 opposite to the first principal surface.

That is, in the semiconductor chip unit 4, the semiconductor chip 1 mounted above the first principal surface of the interposer 3 is electrically coupled to the terminal electrodes 35 on the second principal surface of the interposer 3 via the interconnect layer 33, the post electrodes 34, and the through electrodes 32.

A plurality of semiconductor chip units 4 shown in FIGS. 5 and 6 are stacked, thereby providing three-dimensional stack packaging of semiconductor chips without through electrodes as shown in FIG. 7. In a semiconductor chip stack module shown in FIG. 7, four semiconductor chip units 4 are stacked above a mounting substrate 2 with semiconductor chips 1 facing downward. Post electrodes 34 of the first to third semiconductor chip units 4 from the top are bonded to terminal electrodes 35 of the underlying semiconductor chip units 4. Post electrodes 34 of the lowermost semiconductor chip unit 4 are electrically coupled to the mounting substrate 2. Solder balls 21 are provided on the lower surface of the mounting substrate 2.

As such, interposers are provided above and below semiconductor chips without through electrodes and the semiconductor chips are flip-chip bonded, thereby enabling three-dimensional stack packaging of the semiconductor chips.

### SUMMARY

However, in the semiconductor chip stack module according to the conventional art, the semiconductor chip units including the interposers and the semiconductor chips are supported by the metal post electrodes. Since the post electrodes have low stiffness, it is concerned that damages in stacking the chips reduces the yield and reliability of the module.

In the semiconductor chip stack module according to the conventional art, the sizes of the post electrodes cannot be reduced to 100 μm or less to ensure the stiffness. This reduces the number of the post electrodes which can be arranged, thereby reducing the flexibility of the interconnect layout.

In view of the problems, it is an objective of the present disclosure to stack a plurality of semiconductor chips using interposers, thereby miniaturizing a semiconductor device, and improving the yield and reliability of the semiconductor device.

In order to achieve the objective, a semiconductor device according to the present disclosure includes a first interposer; a first semiconductor chip located above a first surface of the first interposer; and a second interposer located in a region above the first surface of the first interposer, in which the first semiconductor chip is not formed. The first interposer includes a first through electrode electrically coupled to the first semiconductor chip, and a second through electrode electrically coupled to the second interposer. A resin fills a space between the first semiconductor chip and the second interposer.

In the semiconductor device according to the present disclosure, the first semiconductor chip and the second interposer are located above the first interposer. The through electrodes electrically coupled to the first semiconductor chip and the second interposer are formed in the first interposer. A plurality of such chip units, each of which includes a single semiconductor chip and two interposers, are stacked, and the upper and lower chip units are electrically coupled by the through electrode provided in, for example, the second interposer. As a result, a plurality of semiconductor chips are stacked to miniaturize a semiconductor device, even if no through electrode is provided in the semiconductor chips themselves. In addition, the second interposer supports the upper chip unit (specifically, the first interposer of the chip unit), thereby reducing damages in stacking the chips and improving the yield and reliability of the device. Where a through electrode is provided in the second interposer to electrically couple the upper and lower chip units, the size of the through electrode is reduced to, for example, about 5 μm, and the number of through electrodes is increased to improve the flexibility of the interconnect layout.

In the semiconductor device according to the present disclosure, the second interposer may include a third through electrode electrically coupled to the second through electrode of the first interposer. This reliably provides electrical coupling between the chip units, each of which includes a single semiconductor chip and two interposers. In this case, an electrode electrically coupling the third through electrode of the second interposer to the second through electrode of the first interposer may be formed on a surface of the second interposer close to the first interposer.

In the semiconductor device according to the present disclosure, an electrode electrically coupled to the first through electrode of the first interposer may be formed on a surface of the first semiconductor chip close to the first interposer.

In the semiconductor device according to the present disclosure, at least part of a side surface of the second interposer may be substantially flush with a side surface of the first interposer.

In the semiconductor device according to the present disclosure, the second interposer may surround the first semiconductor chip. This improves the mechanical strength of the semiconductor device, thereby providing the advantage of protecting the chips.

In the semiconductor device according to the present disclosure, a first interconnect layer electrically coupling the first through electrode to the second through electrode may be formed on a surface of the first interposer opposite to the first semiconductor chip. This reliably provides electrical coupling between the first semiconductor chip and the second interposer.

In the semiconductor device according to the present disclosure, no through electrode may be formed in the first semiconductor chip, or a through electrode may be formed in the first semiconductor chip.

In the semiconductor device according to the present disclosure, each of the first semiconductor chip, the first interposer, and the second interposer may be formed of a silicon substrate. This prevents stress caused by a difference in a coefficient of thermal expansion among the first semiconductor chip, the first interposer, and the second interposer, thereby ensuring the reliability for a long period.

In the semiconductor device according to the present disclosure, at least one of the first interposer or the second interposer may include at least one of an active element or a passive element. In this case, the active element may include a transistor.

The semiconductor device according to the present disclosure may further include a third interposer located above a surface of the first semiconductor chip opposite to the first interposer; and a second semiconductor chip located on a surface of the third interposer opposite to the first semiconductor chip. The third interposer may be supported by the second interposer, and may include a fourth through electrode electrically coupled to the second semiconductor chip. With this structure, the first semiconductor chip and the second semiconductor chip are stacked using the first to third interposers. In this case, the semiconductor device may further include a fourth interposer located in a region above the opposite surface of the third interposer without the second semiconductor chip. The third interposer may include a fifth through electrode electrically coupled to the fourth interposer. Then, another semiconductor chip is stacked above the second semiconductor chip using the fourth interposer. The fourth interposer may include a sixth through electrode electrically coupled to the fifth through electrode of the third interposer. Alternatively, an electrode electrically coupling the sixth through electrode of the fourth interposer to the fifth through electrode of the third interposer is formed on a surface of the fourth interposer close to the third interposer. Alternatively, a resin may fill a space between the second semiconductor chip and the fourth interposer. Alternatively, a second interconnect layer electrically coupling the fourth through electrode to the fifth through electrode may be formed on a surface of the third interposer opposite to the second semiconductor chip. This reliably provides electrical coupling between the second semiconductor chip and the fourth interposer. In this case, where the second interconnect layer is electrically coupled to the second interposer, the second semiconductor chip is electrically coupled to the first semiconductor chip via the third interposer, the second interconnect layer, the second interposer, and the first interposer. In this case, an electrode electrically coupling the second interconnect layer to the second interposer may be formed on a surface of the second interposer opposite to the first interposer.

Where the semiconductor device according to the present disclosure includes the third interposer above which the second semiconductor chip is mounted, an electrode electrically coupled to the fourth through electrode of the third interposer may be formed on a surface of the second semiconductor chip close to the third interposer. At least part of a side surface of the fourth interposer may be substantially flush with a side surface of the third interposer. Alternatively, the fourth interposer may surround the second semiconductor chip. This improves the mechanical strength of the semiconductor device, thereby providing the advantage of protecting the chips. Alternatively, no through electrode may be formed in the second semiconductor chip, or a through electrode may be formed in the second semiconductor chip. Alternatively, each of the second semiconductor chip and the third interposer are formed of a silicon substrate. This prevents stress caused by a difference in a coefficient of thermal expansion between the second semiconductor chip and the third interposer, thereby ensuring the reliability for a long period. Alternatively, the third interposer may include at least one of an active element or a passive element. In this case, the active element may include a transistor.

The present disclosure miniaturizes a semiconductor device formed by stacking a plurality of semiconductor chips using interposers, and improves the yield and reliability of the semiconductor device.

### BRIEF DESCRIPTION OF THE DRAWINGS

FIG. 1 is a cross-sectional view of a semiconductor device according to an embodiment of the present disclosure.

FIGS. 2A-2D illustrate schematic structures of chip units in the semiconductor device according to the embodiment as viewed from above.

FIG. 3 is a schematic view illustrating that a plurality of semiconductor chips are stacked in the semiconductor device according to the embodiment.

FIG. 4 is a schematic view illustrating that a plurality of semiconductor chips are stacked in a semiconductor device according to a comparison example.

FIG. 5 is a cross-sectional view of a semiconductor chip unit included in the semiconductor device according to conventional art.

FIG. 6 is a top view of the semiconductor chip unit included in the semiconductor device according to the conventional art.

FIG. 7 is a cross-sectional view of the semiconductor device according to the conventional art.

### DETAILED DESCRIPTION

The semiconductor device according to an embodiment of the present disclosure will be described hereinafter with reference to the drawings.

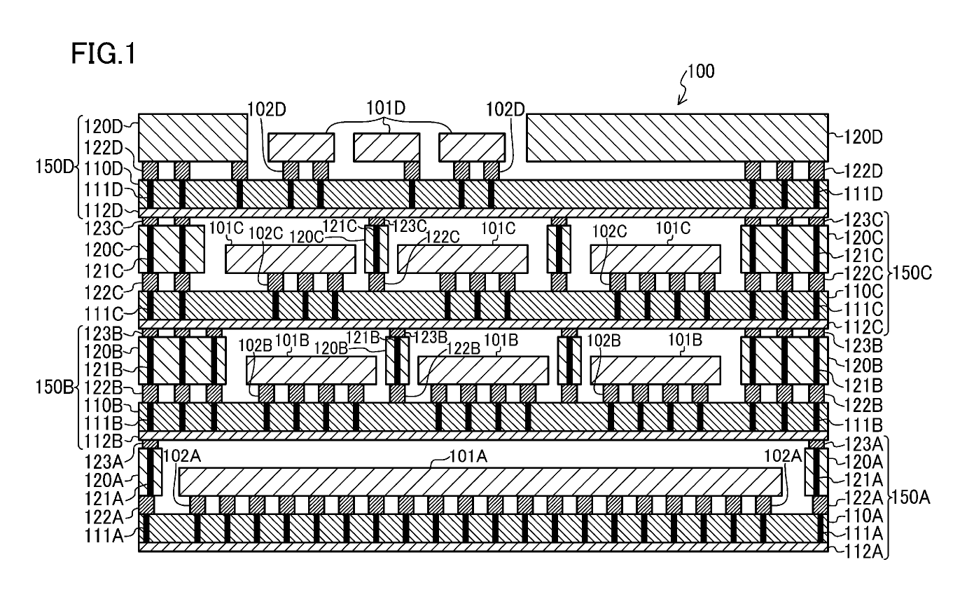

FIG. 1 is a cross-sectional view illustrating an example semiconductor device according to this embodiment, which is formed by stacking four types of semiconductor chips having different sizes using interposers. In this embodiment, the four types of semiconductor chips 101A, 101B, 101C, and 101D mounted in the semiconductor device 100 are conventional semiconductor chips without through electrodes (e.g., TSVs) or re-distribution layers (RDLs). The semiconductor chips 101A, 101B, 101C, and 101D include a plurality of electrode pads 102A, 102B, 102C, and 102D, respectively, each of which has a size of 80 μm square and a pitch of 160 μm. The RDLs are interconnect layers, which have been conceived for rearranging solder bumps for flip-chip bonding. If the positions of the bumps of upper and lower chips are misaligned in a three-dimensional stack, the RDLs are used for rearranging the bumps and aligning the positions of the bumps. That is, while a usual interconnect layer is for transmitting signals and supplying power between transistors in a chip, an RDL is for transmitting signals and supplying power between chips. While a usual interconnect layer is formed by a complicated dual damascene process for miniaturization, an RDL, which has a large size as compared to a usual interconnect layer, is formed by a simple semi-additive process. An additive process is a formation method of an interconnect used in a printed-circuit board, etc. Resist is formed in a region, in which a conductive pattern such as a Cu pattern is not to be formed, and a pattern is formed in the region without the resist by Cu plating, etc. In particular, formation of a conductive pattern by non-electrolytic plating only is called a full addictive process, and formation of a conductive pattern by electrolytic and non-electrolytic plating is called a semi addictive process.

As shown in FIG. 1, a semiconductor device 100 according to this embodiment is formed by sequentially stacking from the bottom, chip units 150A, 150B, 150C, and 150D including the semiconductor chips 101A, 101B, 101C, and 101D, respectively.

The lowermost chip unit 150A includes an interposer 110A, the semiconductor chip 101A located above a first surface of the interposer 110A, and an interposer 120A located in a region above the first surface of the interposer 110A without the semiconductor chip 101A. The interposer 110A has a plurality of through electrodes 111A. The interposer 120A has a plurality of through electrodes 121A. Ones of the through electrodes 111A of the interposer 110A located below the semiconductor chip 101A are electrically coupled to the semiconductor chip 101A via the electrode pads 102A. Ones of the through electrodes 111A of the interposer 110A located below the interposer 120A are electrically coupled to the through electrodes 121A of the interposer 120A via electrode pads 122A provided on the surface of the interposer 120A close to the interposer 110A.

An interconnect layer 112A such as an RDL is formed on the surface of the interposer 110A opposite to the semiconductor chip 101A. The interconnect layer 112A electrically couples the through electrodes 111A, which are electrically coupled to the semiconductor chip 101A, to the through electrodes 111A, which are electrically coupled to the through electrodes 121A of the interposer 120A. That is, the semiconductor chip 101A is electrically coupled to the through electrodes 121A of the interposer 120A via the interconnect layer 112A.

Electrode pads 123A, which electrically couple the upper chip unit 150B to the through electrodes 121A of the interposer 120A, are formed on the surface of the interposer 120A opposite to the interposer 110A. That is, the chip unit 150B (specifically, an interposer 110B of the chip unit 150B) is supported by the interposer 120A.

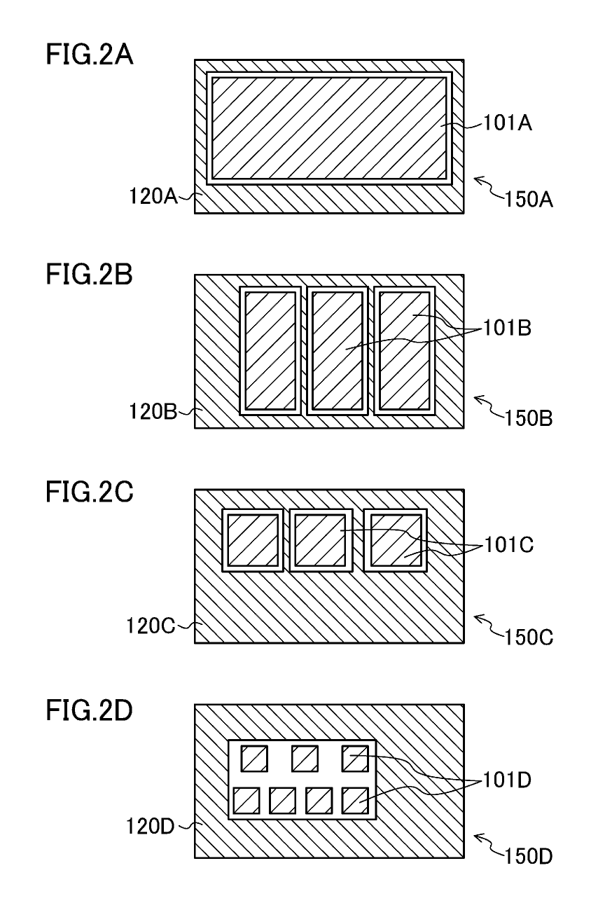

FIG. 2A illustrates the schematic structure of the lowermost chip unit 150A as viewed from above. As shown in FIG. 2A, in the chip unit 150A, the interposer 120A surrounds the single semiconductor chip 101A. The outer side surfaces of the interposer 120A are substantially flush with the side surfaces of the interposer 110A. In other words, the interposer 120A has a shape formed by extracting the semiconductor chip 101A and its periphery from the interposer 110A. A resin may fill the space between the semiconductor chip 101A and the interposer 120A, or the space between the semiconductor chip 101A and the interposer 120A may be hollow.

The second chip unit 150B from the bottom includes the interposer 110B located above the surface of the semiconductor chip 101A opposite to the interposer 110A, the semiconductor chips 101B located above the surface of the interposer 110B opposite to the semiconductor chip 101A, and an interposer 120B located in a region above the opposite surface of the interposer 110B without the semiconductor chips 101B. The interposer 110B has a plurality of through electrodes 111B. The interposer 120B has a plurality of through electrodes 121B. Ones of the through electrodes 111B of the interposer 110B located below the semiconductor chips 101B are electrically coupled to the semiconductor chips 101B via the electrode pads 102B. Ones of the through electrodes 111B of the interposer 110B located below the interposer 120B are electrically coupled to the through electrodes 121B of the interposer 120B via electrode pads 122B provided on the surface of the interposer 120B close to the interposer 110B.

An interconnect layer 112B such as an RDL is formed on the surface of the interposer 110B opposite to the semiconductor chips 101B. The interconnect layer 112B electrically couples the through electrodes 111B, which are electrically coupled to the semiconductor chips 101B, to the through electrodes 111B, which are electrically coupled to the through electrodes 121B of the interposer 120B. That is, the semiconductor chips 101B are electrically coupled to the through electrodes 121B of the interposer 120B via the interconnect layer 112B. The interconnect layer 112B is electrically coupled to the through electrodes 121A of the interposer 120A via the electrode pads 123A. As a result, the semiconductor chip 101A is electrically coupled to the semiconductor chips 101B via the electrode pads 102A, the through electrodes 111A, the interconnect layer 112A, the through electrodes 111A, the electrode pads 122A, the through electrodes 121A, the electrode pads 123A, the interconnect layer 112B, the through electrodes 111B, and the electrode pads 102B.

Electrode pads 123B, which electrically couple the upper chip unit 150C to the through electrodes 121B of the interposer 120B, are formed on the surface of the interposer 120B opposite to the interposer 110B. That is, the chip unit 150C (specifically, an interposer 110C of the chip unit 150C) is supported by the interposer 120B.

FIG. 2B illustrates the schematic structure of the second chip unit 150B from the bottom as viewed from above. As shown in FIG. 2B, in the chip unit 150B, the interposer 120B surrounds the three semiconductor chips 101B. The outer side surfaces of the interposer 120B are substantially flush with the side surfaces of the interposer 110B. In other words, the interposer 120B has a shape formed by extracting the semiconductor chips 101B and their peripheries from the interposer 110B. A resin may fill the space between each of the semiconductor chips 101B and the interposer 120B, or the space between each of the semiconductor chips 101B and the interposer 120B may be hollow.

The third chip unit 150C from the bottom includes the interposer 110C located above the surfaces of the semiconductor chips 101B opposite to the interposer 110B, the semiconductor chips 101C located above the surface of the interposer 110C opposite to the semiconductor chips 101B, and an interposer 120C located in a region above the opposite surface of the interposer 110C without the semiconductor chips 101C. The interposer 110C has a plurality of through electrodes 111C. The interposer 120C has a plurality of through electrodes 121C. Ones of the through electrodes 111C of the interposer 110C located below the semiconductor chips 101C are electrically coupled to the semiconductor chips 101C via the electrode pads 102C. Ones of the through electrodes 111C of the interposer 110C located below the interposer 120C are electrically coupled to the through electrodes 121C of the interposer 120C via electrode pads 122C provided on the surface of the interposer 120C close to the interposer 110C.

An interconnect layer 112C such as an RDL is formed on the surface of the interposer 110C opposite to the semiconductor chips 101C. The interconnect layer 112C electrically couples the through electrodes 111C, which are electrically coupled to the semiconductor chips 101C, to the through electrodes 111C, which are electrically coupled to the through electrodes 121C of the interposer 120C. That is, the semiconductor chips 101C are electrically coupled to the through electrodes 121C of the interposer 120C via the interconnect layer 112C. The interconnect layer 112C is electrically coupled to the through electrodes 121B of the interposer 120B via the electrode pads 123B. As a result, the semiconductor chips 101B are electrically coupled to the semiconductor chips 101C via the electrode pads 102B, the through electrodes 111B, the interconnect layer 112B, the through electrodes 111B, the electrode pads 122B, the through electrodes 121B, the electrode pads 123B, the interconnect layer 112C, the through electrodes 111C, and the electrode pads 102C.

Electrode pads 123C, which electrically couple the upper chip unit 150D to the through electrodes 121C of the interposer 120C, are formed on the surface of the interposer 120C opposite to the interposer 110C. That is, the chip unit 150D (specifically, an interposer 110D of the chip unit 150D) is supported by the interposer 120C.

FIG. 2C illustrates the schematic structure of the third chip unit 150C from the bottom as viewed from above. As shown in FIG. 2C, in the chip unit 150C, the interposer 120C surrounds the three semiconductor chips 101C. The outer side surfaces of the interposer 120C are substantially flush with the side surfaces of the interposer 110C. In other words, the interposer 120C has a shape formed by extracting the semiconductor chips 101C and their peripheries from the interposer 110C. A resin may fill the space between each of the semiconductor chips 101C and the interposer 120C, or the space between each of the semiconductor chips 101C and the interposer 120C may be hollow.

The fourth chip unit 150D from the bottom (i.e., the uppermost chip unit) includes the interposer 110D located above the surfaces of the semiconductor chips 101C opposite to the interposer 110C, the semiconductor chips 101D located above the surface of the interposer 110D opposite to the semiconductor chips 101C, and an interposer 120D located in a region above the opposite surface of the interposer 110D without the semiconductor chips 101D. The interposer 110D has a plurality of through electrodes 111D. Ones of the through electrodes 111D of the interposer 110D located below the semiconductor chips 101D are electrically coupled to the semiconductor chips 101D via the electrode pads 102D. Ones of the through electrodes 111D of the interposer 110D located below the interposer 120D are electrically coupled to the interposer 120D via electrode pads 122D provided on the surface of the interposer 120D close to the interposer 110D.

An interconnect layer 112D such as an RDL is formed on the surface of the interposer 110D opposite to the semiconductor chips 101D. The interconnect layer 112D electrically couples the through electrodes 111D, which are electrically coupled to the semiconductor chips 101D, to the through electrodes 111D, which are electrically coupled to the interposer 120D. That is, the semiconductor chips 101D are electrically coupled to the interposer 120D via the interconnect layer 112D. The interconnect layer 112D is electrically coupled to the through electrodes 121C of the interposer 120C via the electrode pads 123C. As a result, the semiconductor chips 101C are electrically coupled to the semiconductor chips 101D via the electrode pads 102C, the through electrodes 111C, the interconnect layer 112C, the through electrodes 111C, the electrode pads 122C, the through electrodes 121C, the electrode pads 123C, the interconnect layer 112D, the through electrodes 111D, and the electrode pads 102D.

FIG. 2D illustrates the schematic structure of the fourth chip unit 150D from the bottom (i.e., the uppermost chip unit) as viewed from above. As shown in FIG. 2D, in the chip unit 150D, the interposer 120D surrounds the seven semiconductor chips 101D. The outer side surfaces of the interposer 120D are substantially flush with the side surfaces of the interposer 110D. In other words, the interposer 120D has a shape formed by extracting the semiconductor chips 101D and their peripheries from the interposer 110D. A resin may fill the space between each of the semiconductor chips 101D and the interposer 120D, and the space between adjacent ones of the semiconductor chips 101D, the space between each of the semiconductor chips 101D and the interposer 120D, and the space between adjacent ones of the semiconductor chips 101D may be hollow.

As described above, in this embodiment, in the chip units 150A-150D, the semiconductor chips 101A-101D and the interposers 120A-120D are located above the interposers 110A-110D, respectively. The interposers 110A-110D have the through electrodes 111A-111D, which are electrically coupled to the semiconductor chips 101A-101D and the interposers 120A-120D, respectively. The chip units 150A-150D are stacked, and the upper and lower chip units are electrically coupled by the through electrodes 121A-121C provided in the interposers 120A-120C, respectively. Thus, even if the semiconductor chips 101A-101D themselves do not have through electrodes, the semiconductor chips 101A-101D are stacked to miniaturize the semiconductor device 100 while electrically coupling the semiconductor chips 101A-101D existing in the different layers.

In this embodiment, the interposers 120A-120C support the upper chip units 150B-150D (specifically, the interposers 110B-110D of the chip units 150B-150D), respectively, thereby reducing damages in stacking the chips and improving the yield and reliability. In particular, in this embodiment, the interposers 120A-120C surrounding the semiconductor chips 101A-101C support the upper chip units 150B-150D, respectively, thereby obtaining sufficient stiffness of the semiconductor device 100. In this embodiment, part of the interposer 120B is interposed between the relatively small semiconductor chips 101B arranged in the chip unit 150B, and part of the interposer 120C is interposed between the relatively small semiconductor chips 101C arranged in the chip unit 150C, thereby further improving the stiffness of the semiconductor device 100 having a three-dimensional stack structure.

In this embodiment, when the through electrodes 121A-121C are provided in the interposers 120A-120C, respectively, to electrically couple the upper and lower chip units (the chip unit 150A and the chip unit 150B, the chip unit 150B and the chip unit 150C, and the chip unit 150C and the chip unit 150D), the sizes of the through electrodes 121A-121C are reduced to about 5 μm to increase the number of the provided through electrodes 121A-121C. This improves the flexibility of the interconnect layout.

In this embodiment, the interposers 120A-120D surround the semiconductor chips 101A-101D, respectively, to improve the mechanical strength of the semiconductor device 100, thereby improving the advantage of protecting the semiconductor chips 101A-101D.

An example method of manufacturing the semiconductor device 100 according to this embodiment, which is the stack of the semiconductor chips 101A-101D, will be briefly described. First, wafers, on which the interposers 120A-120D of the chip units 150A-150D (i.e., from which the regions for providing the semiconductor chips 101A-101D are extracted) are formed, are stacked above other wafers, on which the interposers 110A-110D of the chip units 150A-150D are formed, respectively. Then, the semiconductor chips 101A-101D are flip-chip bonded to the regions of the interposers 110A-110D surrounded by the interposers 120A-120D, respectively. Next, the wafers, on which the interposers 110A-110D of the chip units 150A-150D are formed, and the wafers, on which the interposers 120A-120D of the chip units 150A-150D are formed, are diced at the same time to form the chip units 150A-150D, respectively. Finally, the chip units 150A-150D are sequentially stacked from the bottom, i.e., the interposers 110B-110D of the chip units 150B-150D are stacked above the interposers 120A-120C of the chip units 150A-150C, respectively, thereby obtaining the semiconductor device 100 according to this embodiment. Where resins fill the spaces which are formed in combining the interposers 110A-110D, the interposers 120A-120D, and the semiconductor chips 101A-101D of the chip units 150A-150D, respectively; the filling of the resins is performed between the flip-chip bonding and the dicing.

The area occupied by the chips in the semiconductor device 100 according to this embodiment formed by stacking the semiconductor chips 101A-101D will be compared to the area occupied by the chips in a semiconductor device according to a comparison example. The semiconductor device according to the comparison example is formed by individually packaging a plurality of semiconductor chips having areas equal to those of the semiconductor chips 101A-101D as is conventionally done, and arranging the semiconductor chips on a printed-circuit board.

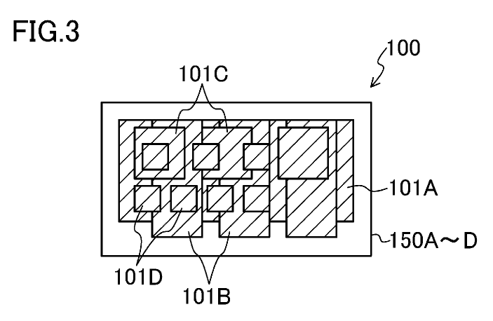

FIG. 3 is a schematic view illustrating that the semiconductor chips 101A-101D (i.e., the chip units 150A-150D) are stacked in the semiconductor device 100 according to this embodiment. The chip units 150A-150D have the same planar shapes (e.g., 3.6 mm×6.4 mm) and an area of, e.g., 23.0 mm². Therefore, the semiconductor device 100 according to this embodiment requires the area of 23.0 mm² for stacking all the semiconductor chips 101A-101D.

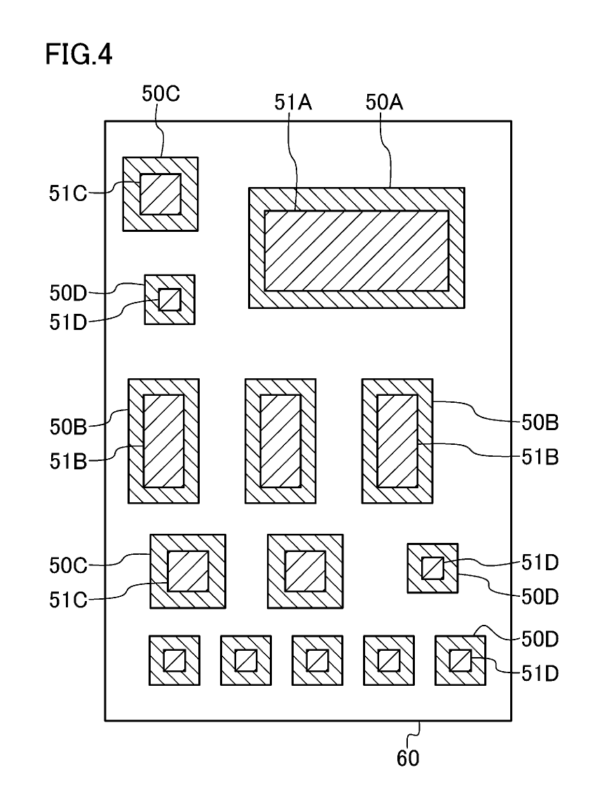

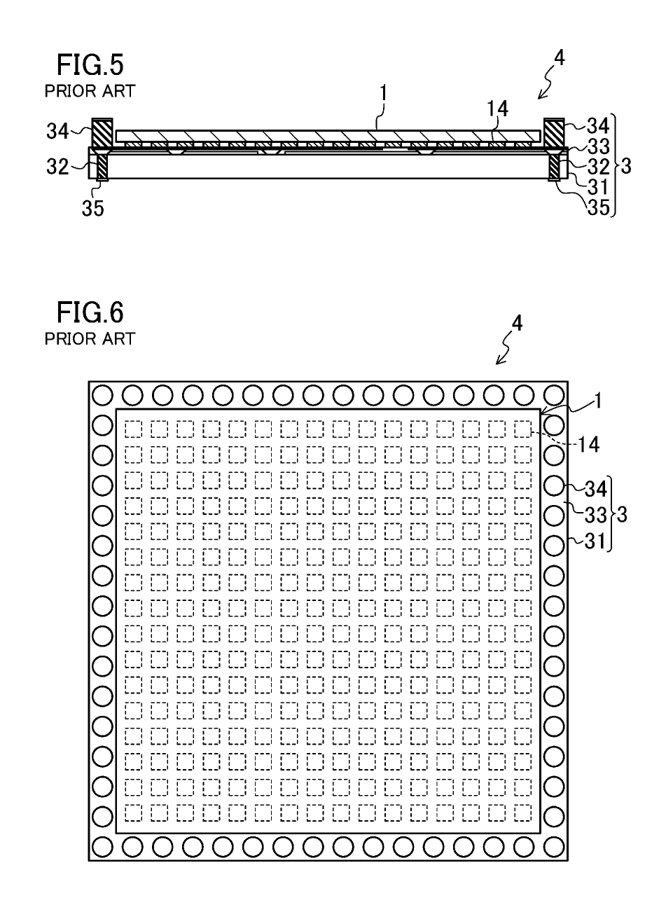

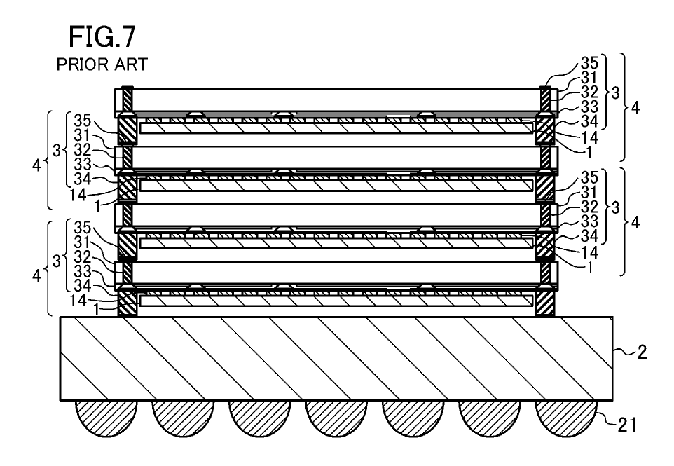

FIG. 4 is a schematic view illustrating that the plurality of semiconductor chips having areas equal to those of the semiconductor chips 101A-101D are individually packaged and arranged on the printed-circuit board in the semiconductor device according to the comparison example. As shown in FIG. 4, a single semiconductor chip 51A having an area equal to that of the semiconductor chip 101A is located on a printed-circuit board 60 in the form of a package 50A. Three semiconductor chips 51B having areas equal to those of the semiconductor chips 101B are located on the printed-circuit board 60 in the forms of packages 50B. Three semiconductor chips 51C having areas equal to those of the semiconductor chips 101C are located on the printed-circuit board 60 in the forms of packages 50C. Seven semiconductor chips 51D having areas equal to those of the semiconductor chips 101D are located on the printed-circuit board 60 in the forms of packages 50D. The area of the package 50A is, for example, 23.0 mm² (3.6 mm×6.4 mm), which is equal to the areas of the chip units 150A-150D. The area of the package 50B is, for example, 7.8 mm² (3.7 mm×2.1 mm). The area of the package 50C is, for example, 5.1 mm² (2.2 mm×2.3 mm). The area of the package 50D is, for example, 2.1 mm² (1.4 mm×1.5 mm). The printed-circuit board 60 requires an area of, for example, 216.0 mm² (18.0 mm×12.0 mm) for mounting all the semiconductor chips 51A-51D (i.e., the packages 50A-50D) in view of the region for providing printed wiring which electrically couples the chips.

From the comparison of the results, it is found that the area of the semiconductor device 100 according to this embodiment requires about 1/10 of the area of the semiconductor device according to the comparison example. That is, in this embodiment, the upper and lower semiconductor chips (101A and 101B, 101B and 101C, and 101C and 101D) i.e., the upper and lower chip units (150A and 150B, 150B and 150C, and 150C and 150D) are coupled via the through electrodes 121A-121C in the interposers 120A-120C. The area is thus largely reduced as compared to the conventional technique, even when semiconductor chips without through electrodes are stacked as the semiconductor chips 101A-101D.

In this embodiment, usage of the semiconductor chips 101A-101D is not limited. However, where the semiconductor device 100 is for a mobile device, the semiconductor chip 101A may be an application processor, the semiconductor chips 101B may be flash memories, the semiconductor chips 101C may be a baseband processing LSI and an RF processing LSI, and the semiconductor chips 101D may be power supply ICs or various sensors.

While in this embodiment, the four types of semiconductor chips 101A-101D are stacked, the number of the stacked semiconductor chips is clearly not limited thereto.

In this embodiment, the materials of the substrates of the semiconductor chips 101A-101D, the interposers 110A-110D, and the interposers 120A-120D are not particularly limited. However, where the substrates of the semiconductor chips 101A-101D are made of, for example, silicon, the substrates of the interposers 110A-110D and the interposers 120A-120D are preferably made of silicon, as well. This prevents stress caused by a difference in a coefficient of thermal expansion among the semiconductor chips 101A-101D, the interposers 110A-110D, and the interposers 120A-120D, thereby ensuring the reliability for a long period.

While in this embodiment, through electrodes are not provided in the semiconductor chips 101A-101D, through electrodes may be provided in at least one of the semiconductor chips 101A-101D.

In this embodiment, the through electrodes 111A-111D and the through electrodes 121A-121C are provided in the interposers 110A-110D and the interposers 120A-120C, respectively. In addition, at least one of an active element or a passive element may be provided in at least one of the interposers 110A-110D and the interposers 120A-120C. For example, a transistor may be provided as the active element. For example, at least one of a resistor, a capacitor, or a coil may be provided as the passive element. In the interposers 110A-110D and the interposers 120A-120C, interconnects (including vias) for electrically coupling the front to the back of the interposers may be provided instead of the through electrodes 111A-111D and the through electrodes 121A-121C. Note that, the sizes of the through electrode can be reduced to, for example, about 5 μm. Thus, where through electrodes are provided in the interposers, numbers of through electrodes are arranged for electrical coupling between the upper and lower semiconductor chips (i.e., between the upper and lower chip units) to improve the flexibility of the interconnect layout.

While in this embodiment, the electrode pads 102A-102D are provided in the semiconductor chips 101A-101D, the tops of through electrodes provided in the semiconductor chips 101A-101D may be exposed from the surfaces of the chips to be used as external electrodes.

In this embodiment, the interposers 120A-120D are provided with the electrode pads 122A-122D, which are electrically coupled to the interposers 110A-110D, respectively. Instead, the tops of the through electrodes provided in the interposers 120A-120D may be exposed from the surfaces of interposers to be used as external electrodes. In addition, the interposers 120A-120C are provided with the electrode pads 123A-123C, which are electrically coupled to the interposers 110B-110D. Instead, the tops of the through electrodes provided in the interposers 120A-120C may be exposed from the surfaces of interposers to be used as external electrodes.

In this embodiment, the space formed by the interposers 110A-110D and the interposers 120A-120D (except for the regions for providing the semiconductor chips 101A-101D) may be hollow, or may be filled with a resin.

While in this embodiment, the planar shapes of the chip units 150A-150D are the same, the planar shapes of the chip units 150A-150D may be different. While the outer side surfaces of the interposers 120A-120D are flush with the side surfaces of the interposers 110A-110D, respectively, the surfaces may not be flush.

The semiconductor device 100 according to this embodiment, which is formed by stacking the semiconductor chips 101A-101D, may be clearly mounted on a substrate other than a mounting substrate.

As described above, the present disclosure miniaturizes a semiconductor device by stacking a plurality of semiconductor chips using interposers, and improves the yield and reliability of the semiconductor device, and is thus suitable for a three-dimensional stack of a plurality of semiconductor chips.

What is claimed is:

1. A semiconductor device, comprising:
a first interposer;
a first semiconductor chip located above a first surface of the first interposer; and
a second interposer located in a region above the first surface of the first interposer, in which the first semiconductor chip is not formed, wherein
the first interposer includes
a first through electrode electrically coupled to the first semiconductor chip, and
a second through electrode electrically coupled to the second interposer, and
a resin fills a space between the first semiconductor chip and the second interposer.

2. The semiconductor device of claim 1, wherein
the second interposer includes a third through electrode electrically coupled to the second through electrode of the first interposer.

3. The semiconductor device of claim 2, wherein
an electrode electrically coupling the third through electrode of the second interposer to the second through electrode of the first interposer is formed on a surface of the second interposer close to the first interposer.

4. The semiconductor device of claim 1, wherein
an electrode electrically coupled to the first through electrode of the first interposer is formed on a surface of the first semiconductor chip close to the first interposer.

5. The semiconductor device of claim 1, wherein
at least part of a side surface of the second interposer is substantially flush with a side surface of the first interposer.

6. The semiconductor device of claim 1, wherein
the second interposer surrounds the first semiconductor chip.

7. The semiconductor device of claim 1, wherein
a first interconnect layer electrically coupling the first through electrode to the second through electrode is formed on a surface of the first interposer opposite to the first semiconductor chip.

8. The semiconductor device of claim 1, wherein
no through electrode is formed in the first semiconductor chip.

9. The semiconductor device of claim 1, wherein
a through electrode is formed in the first semiconductor chip.

10. The semiconductor device of claim 1, wherein
each of the first semiconductor chip, the first interposer, and the second interposer is formed of a silicon substrate.

11. The semiconductor device of claim 1, wherein
at least one of the first interposer or the second interposer includes at least one of an active element or a passive element.

12. The semiconductor device of claim 11, wherein
the active element includes a transistor.

13. The semiconductor device of claim 1, further comprising:
a third interposer located above a surface of the first semiconductor chip opposite to the first interposer; and
a second semiconductor chip located on a surface of the third interposer opposite to the first semiconductor chip; wherein
the third interposer is supported by the second interposer, and includes a fourth through electrode electrically coupled to the second semiconductor chip.

14. The semiconductor device of claim 13, further comprising
a fourth interposer located in a region above the opposite surface of the third interposer without the second semiconductor chip, wherein
the third interposer includes a fifth through electrode electrically coupled to the fourth interposer.

15. The semiconductor device of claim 14, wherein
the fourth interposer includes a sixth through electrode electrically coupled to the fifth through electrode of the third interposer.

16. The semiconductor device of claim 15, wherein
an electrode electrically coupling the sixth through electrode of the fourth interposer to the fifth through electrode of the third interposer is formed on a surface of the fourth interposer close to the third interposer.

17. The semiconductor device of claim 14, wherein
a resin fills a space between the second semiconductor chip and the fourth interposer.

18. The semiconductor device of claim 14, wherein
a second interconnect layer electrically coupling the fourth through electrode to the fifth through electrode is formed on a surface of the third interposer opposite to the second semiconductor chip.

19. The semiconductor device of claim 18, wherein
the second interconnect layer is electrically coupled to the second interposer.

20. The semiconductor device of claim 19, wherein
an electrode electrically coupling the second interconnect layer to the second interposer is formed on a surface of the second interposer opposite to the first interposer.

21. The semiconductor device of claim 13, wherein
an electrode electrically coupled to the fourth through electrode of the third interposer is formed on a surface of the second semiconductor chip close to the third interposer.

22. The semiconductor device of claim 14, wherein
at least part of a side surface of the fourth interposer is substantially flush with a side surface of the third interposer.

23. The semiconductor device of claim 14, wherein
the fourth interposer surrounds the second semiconductor chip.

24. The semiconductor device of claim 13, wherein
no through electrode is formed in the second semiconductor chip.

25. The semiconductor device of claim 13, wherein
a through electrode is formed in the second semiconductor chip.

26. The semiconductor device of claim 13, wherein
each of the second semiconductor chip and the third interposer is formed of a silicon substrate.

27. The semiconductor device of claim 13, wherein
the third interposer includes at least one of an active element or a passive element.

28. The semiconductor device of claim 27, wherein
the active element includes a transistor.
